(19) United States
(12) Patent Application Publication
(10) Pub. No.: US 2018/0339506 A1
(43) Pub. Date: Nov. 29, 2018

(54) PRINTHEAD WITH TWO PRINTING PLATES FOR PRODUCING AT LEAST ONE GRIDLINE ON AN UPPER SURFACE OF A TARGET SUBSTRATE IN FORWARD AND BACKWARD DIRECTIONS

(71) Applicants: Hanwha Q CELLS Malaysia Sdn. Bhd., Cyberjava, Selangor (MY); Hanwha Q CELLS GmbH, Bitterfeld-Wolfen (DE)

(72) Inventor: Viknesvaran Krishnan, Klang Selangor (MY)

(73) Assignees: Hanwha Q CELLS Malaysia Sdn. Bhd., Cyberjava, Selangor (MY); Hanwha Q CELLS GmbH, Bitterfeld-Wolfen (DE); Hanwha Q CELLS GmbH, Bitterfeld-Wolfen (DE)

(21) Appl. No.: 15/775,322

(22) PCT Filed: Nov. 11, 2016
(86) PCT No.: PCT/EP2016/077502

§ 371 Date: May 10, 2018

(30) Foreign Application Priority Data
Nov. 12, 2015 (MY) PI2015704084

(51) Int. Cl. B41F 15/08; B41F 15/46; H01L 31/0224; B41F 15/34; B41M 1/12

(52) U.S. Cl. CPC B41F 15/0881; B41F 15/46; B41P 2215/50; B41F 15/34; B41M 1/12; H01L 31/022425

(57) ABSTRACT

Printheads may be utilized to produce at least one gridline on an upper surface of a target substrate, in particular for producing a pattern for a solar cell structure, wherein the printheads may enable a printing in the forward and an opposite backward direction at the same time to, for example, increase the relative speed the printing procedure and to improve the screen or stencil printing process.

### CROSS-REFERENCE TO RELATED APPLICATIONS

This application is a national phase entry under 35 U.S.C. § 371 of International Patent Application PCT/EP2016/077502, filed Nov. 11, 2016, designating the United States of America and published in English as International Patent Publication WO 2017/081297 A1 on May 18, 2017, which claims the benefit under Article 8 of the Patent Cooperation Treaty to Malaysian Patent Application Serial No. PI2015704084, filed Nov. 12, 2015, the disclosure of each of which is hereby incorporated herein in its entirety by this reference.

### TECHNICAL FIELD

This disclosure relates to the field of printheads for producing at least one gridline, in particular, a plurality of parallel gridlines, on an upper surface of a target substrate, in particular for producing a pattern for a solar cell structure.

### BACKGROUND

The basic principle of the process of screen printing is the use of a mesh screen to reproduce the same image over and over again. The way that screen printing is used in the process of making solar cells is that photovoltaic (PV) solar cells are often metalized through a screen-printing process. This is the application of different types of metallization pastes onto, e.g., a c-Si cell. Thereby, the paste is applied to a mesh screen and pushed through with a squeegee to transfer the paste on the open image area to the desired substrate. This process can be repeated as many times as the screen materials will last.

According to the state of the art, printheads for squeezing the paste are configured and adapted to work in one direction only. In a first step, according to the methods known in the state of the art, the mesh screen is flooded with the paste and then the squeegee is moved into a first direction over the mesh screen and the paste to transfer the same on the substrate. As the width of the squeegee is not necessarily the width of the substrate, the squeegee is lifted up, moved back in the lifted position in the opposite direction to the initial starting point of its movement, and then the process is repeated.

The disadvantages of the printheads for screen printing according to the state of the art are that the printing process is time consuming as the printhead is moved back without printing and the paste itself is not used efficiently by flooding the paste over the mesh screen, while not all of the paste may be used.

### BRIEF SUMMARY

The object of the present invention is therefore to fasten the printing of gridlines on a target substrate and to provide a minimized paste loss and an efficient paste transfer to the substrate.

This object is solved by a printhead for producing at least one gridline, in particular, a plurality of parallel gridlines, on an upper surface of a target substrate, in particular for producing a pattern for a solar cell structure, by screen or stencil printing having at least one inlet port, at least one dispensing orifice, and one or more flow channels communicating between the at least one inlet port and the at least one dispensing orifice, further comprising at least two printing plates or blades that are placed in independently definable angles relative to the upper surface of the target substrate, wherein the at least two printing plates are independently movable between a printing position and a stop position, and wherein at least a first printing plate and at least a second printing plate are arranged at opposite sites of the at least one dispensing orifice, and wherein in the printing position the printing plates are arranged closer to the upper surface of a target substrate than in the stop position.

The word “exemplary” is used herein to mean “serving as an example, instance, or illustration.” Any implementation described herein as “exemplary” is not necessarily to be construed as preferred or advantageous over other implementations.

The printhead according to the present disclosure may be used for producing fine lines on a substrate, which is based on multi-crystalline silicon wafers, whereby the fine line produced is according to a solar cell structure. The fine lines are defined as “fingers.” Screen or stencil printing is applied in order to produce the fine lines (fingers). The printhead may comprise an inlet port that can have single or multiple channels, which may be used to connect tubing supplying solar cell paste whereby solar paste will be supplied continuously.

The printhead may comprise a material feed mechanism, whereby the inlet port on the printhead will be connected with paste supplying tubing and the paste will be forced via a force to fill up the space in between the plate and the screen or stencil.

The printhead may comprise a transport mechanism and material feed system. The material may be forced through a channel to the dispensing orifice in front of the blades. The transport mechanism will move the printhead to the specified gap between the stencil/screen and wafer surface. The blades with specified angles, will move forward as per position defined and stop as per position defined.

With a printhead according to the present disclosure, it is possible to print with forward direction (Cycle 1) and backward (Cycle 2) direction, e.g., for front side solar cells metalization. Dependent of the printing direction, one of the two printing plates is moved into the printing position, while the second printing plate is in or moved to the stop position. Each blade has independent movement and an up-down movement of each individual blade. Preferably, the two printing plates are arranged opposite to each other in mirrored angles relative to the upper surface of the substrate. Then, in this case, a single squeegee holder thereby provides the paste through the at least one orifice according to process requirements and setup. The triggering for the up-down movement is based on a sensor triggering on the position of printing.

The movement of the printing blades to achieve the desired printing angle and/or to move the printing blades into the stop or printing position is achieved via movement actuated pneumatically, hydraulically and/or by at least one electric motor.

The possible printing mode provided by the printhead according to the present disclosure does not require any flooding mechanism and enables printing of solar cells by opposite movement direction. Thereby, the printhead dispenses the paste directly next to the printing blades during the printing cycles continuously.

Finally, the printhead according to the present disclosure enables printing of solar cells in lesser cycle time as printing is possible in backward and forward directions of the movement of the printhead.

According to one example of the present disclosure, the printhead may comprise at least one controller, wherein the at least one controller is configured and adapted to determine the movement direction of the printhead, and wherein the movement of the printing plates from the printing position to the stop position and reverse is controlled by the controller based on the detected printing position.

By use of such a controller, the printing and stop position of each of the printing plates can be configured automatically depending on the movement direction of the printhead.

Thereby, it may be of advantage according to one embodiment that in case the at least one first printing plate is moved to or in the printing position, the second printing plate is moved to or in the stop position and reciprocally, and wherein the movement between the printing position and the stop position of the printing plates is actuated pneumatically, hydraulically and/or by at least one electric motor which is triggered by the printing position which is triggered by the controller.

This may, in particular, be of advantage as only one blade of the printing head is in contact with the screen or stencil at any time to transfer the paste to the substrate.

According to one example, it may be preferred that a material feed mechanism supplies extrusion material, preferably in the form of a paste, to the inlet port of the printhead such that the extrusion material is selectively forced through the at least one flow channel and exits through the at least one dispensing orifice.

By the efficient paste transfer next to the printing plates, fine line printing is possible. Stable paste composition is provided due to paste rolls at anytime due to the movement of the dual blades.

According to a further example of the present disclosure, the printing blades are arranged in an adjustable angle α in a range of 30° to 70°, in particular, in a range of 45° to 60°, relative to the upper surface of the target substrate, wherein the printing blades preferably have a thickness in a range of 0.05 to 0.5 mm, in particular, in a range of 0.1 to 0.3 mm and, wherein preferably at least one of the printing blades comprises or consists of stainless steel.

Such angles of the printing plates have shown to be advantageous.

Moreover, according to one example of the present disclosure, at least one side wiper is arranged at or adjacent to at least one of the printing blades, in particular, each printing blade comprises at least one side wiper, preferably, two side wipers arranged at opposite sides of each of the printing blades, wherein the at least one side wiper is configured and adapted to create a limited area for the movement and circulation of the extrusion material, preferably, in the form of a paste and, in particular, also providing effective roll of the extrusion material at both printing directions and also minimizing the hardening of extrusion material on the substrate surface area.

The side wipers according to the present disclosure allow the paste to be dispensed in a restricted area. Thereby, the paste losses are significantly reduced via a reduction of the paste being exposed to unprinted areas. Instead, the paste is dispensed directly next to the first or second printing plate. The side wipers may be configured and arranged in order to create a minimum area for the solar cell paste movement and circulation, while also providing effective roll of the solar cell paste at both printing directions in order to ensure effective solar paste transfer from the stencil or screen to a wafer surface. The side wipers may be made of rubber or polyurethane material and supported by steel frames.

Furthermore, according to one example of the present disclosure a transport mechanism is provided for supporting the printhead and/or the target substrate, and for moving the printhead relative to the target substrate such that extrusion material, preferably in form of a paste, exiting the at least one dispensing orifice forms the at least one gridline on the upper surface of the target substrate.

According to a further example of the present disclosure, a printhead may further comprise means for controlling the material feed mechanism and the transport mechanism such that during a first time period, a material feed mechanism forces an extrusion material, preferably, in form of a paste, through the at least one dispensing orifice, while a transport mechanism moves the printhead over the target substrate in a first direction such that first structures are formed on the target substrate starting from or adjacent to a first side edge of the target substrate, wherein at least the first printing blade is in the printing position and at least the second printing blade is in the stop position, and during a second time period, the material feed mechanism forces the extrusion material through the at least one dispensing orifice while the transport mechanism moves the printhead over the target substrate in a second direction opposite to the first direction such that first and/or second structures are formed on the target substrate, wherein at least the second printing blade is in the printing position and at least the first printing blade is in the stop position.

Finally, according to one example, the printhead may comprise an connection to the integrated software of a printing machine, which indicates the present printing mode, wherein the software is capable of triggering the first and second blades to start movement according to the positions and perform the function continuously.

Furthermore, the present invention provides a use of a printhead according to the present disclosure for producing or within production of a solar cell.

Moreover, the present disclosure provides a method for producing at least one gridline, in particular, a plurality of parallel gridlines, on an upper surface of a target substrate, in particular for producing a pattern solar cell structure, by screen or stencil printing using a printhead according to the disclosure, wherein the method comprises during a first time period, causing a material feed mechanism to force a gridline material through the at least one dispensing orifice while causing a transport mechanism to move the printhead relative to the target substrate such that first structures are formed on the target substrate starting from or adjacent to a first side edge of the target substrate in a first direction, wherein the first printing blade is in the printing position and the second printing blade is in the stop position; and during a second time period following the first time period, causing the material feed system to force the gridline material through the at least one dispensing orifice while causing the transport mechanism to move the printhead relative to the target substrate in a second direction opposite to the first direction such that first and/or second structures are formed on the target substrate, wherein the second printing blade is in the printing position and the first printing blade is in the stop position.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1 is a schematic side view of an example of a printhead according to an embodiment; and

FIG. 2 is a schematic side view of the printhead shown in FIG. 1 in a back printing cycle.

### DETAILED DESCRIPTION

The various embodiments will be described in detail with reference to the accompanying drawings. Wherever possible, the same reference numbers will be used throughout the drawings to refer to the same or like parts. References made to particular examples and implementations are for illustrative purposes, and are not intended to limit the scope of the invention or the claims.

While illustrative examples are illustrated and described below, it will be appreciated that various changes can be made therein without departing from the spirit and scope of the disclosure. In that regard, the detailed description set forth below, in connection with the accompanying drawings is intended only as a description of various examples of the disclosed subject matter and is not intended to represent the only examples. Each example described in this disclosure is provided merely as an example or illustration and should not be construed as preferred or advantageous over other examples. The illustrative examples provided herein are not intended to be exhaustive or to limit the disclosure to the precise forms disclosed. Similarly, any steps described herein may be interchangeable with other steps, or combinations of steps, in order to achieve the same or substantially similar result.

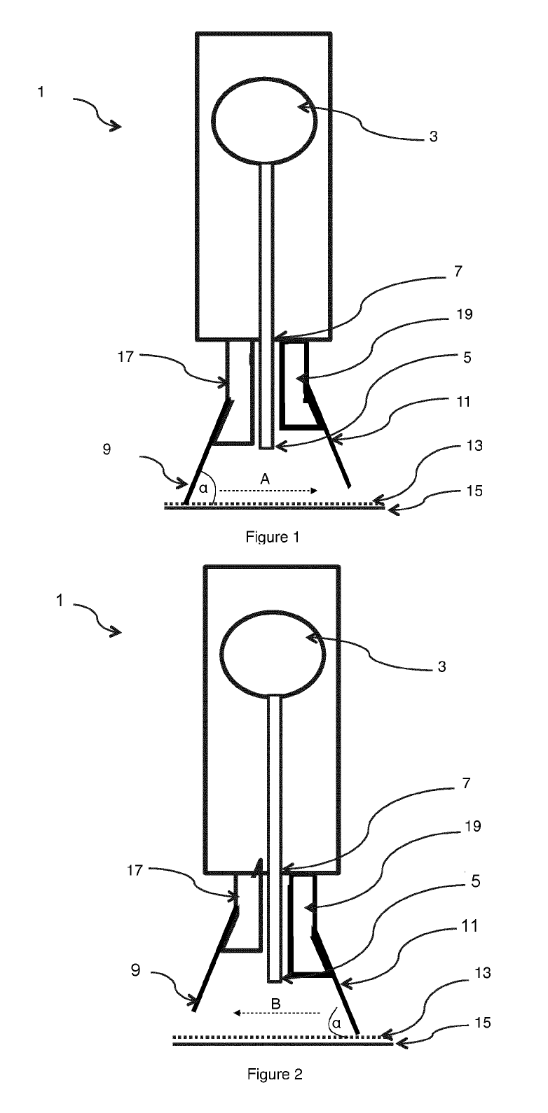

FIG. 1 shows a schematic side view of an example of a printhead according to an example of the present disclosure. Printhead 1 is a printhead for producing at least one gridline of a pattern for a solar cell structure by screen or stencil printing. The printhead 1 has one inlet port (not shown), a squeegee holder 3, at least one dispensing orifice 5, and one flow channel 7 communicating between the inlet port and the at least one dispensing orifice 5.

Two printing plates or blades 9, 11, which are placed in independently definable angles a relative to an upper surface of a target substrate 15, are independently movable between a printing position and a stop position. In FIG. 1, it is shown that a first printing plate 9 is in the printing position while the second printing plate 11 is in the stop position. This allows a printing in the first direction A of the paste through a mesh 13 onto the target substrate 15.

With a printhead according to FIG. 1, it is possible to print with forward direction A and in backward B direction (shown in FIG. 2). Dependent of the printing direction, one of the two printing plates 9, 11 is moved into the printing position, while the second printing plate is in or moved to the stop position. Two printing plates 9, 11 are arranged opposite to each other in mirrored angles relative to the upper surface of the substrate. The squeegee holder 3 provides thereby the paste through the at least one orifice 5 according to process requirements and setup. The triggering for the up-down movement is based on a sensor triggering (not shown) on the position of printing. In case of printing in direction B, the second printing plate 11 is in the printing position and the first printing plate 9 is in the stop position. As can be easily derived from FIGS. 1 and 2, the printhead 1 is able to provide the paste in any printing direction with the same quality. Therefore, the printhead 1 according to the present disclosure enables printing of solar cells in lesser cycle time as printing is possible in backward and forward directions of the movement of the printhead.

The movement between the printing position and the stop position of the printing plates 9, 11 is actuated pneumatically by pneumatic cylinders 17, 19 in the examples shown. Of course, other types of actuation of the printing plates 9, 11 are possible and the pneumatic cylinders shown are just one possible type of realization.

Not shown in FIGS. 1 and 2 are the side wipers, which are arranged at or adjacent to at least one of the printing blades 9, 11, which are configured and adapted to create a limited area for the movement and circulation of the paste and also provide an effective roll of the extrusion material at both printing directions. The side wipers accordingly allow the paste to be dispensed in a restricted area.

Furthermore, the transport mechanism of the present disclosure for supporting the printhead and/or the target substrate, and for moving the printhead relative to the target substrate is not shown in FIGS. 1 and 2.

It is thereby obvious for those skilled in the art that several transport mechanisms are suitable for fulfilling the requirements of screen or stencil printing with a printhead 1 according to the present disclosure.

The features of the present invention disclosed in the description above and in the claims can be used for implementing the invention in its different embodiments both individually and in every possible combination thereof. The preceding description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the following appended claims and the principles and novel features disclosed herein.

1. A printhead for producing a plurality of parallel gridlines, on an upper surface of a target substrate for producing a pattern for a solar cell structure by screen or stencil printing, the printhead having at least one inlet port, at least one dispensing orifice, and one or more flow channels communicating between the at least one inlet port and the at least one dispensing orifice, the printhead further comprising at least two printing plates that are placed in independently definable angles relative to the upper surface of the target substrate, wherein the at least two printing plates are independently movable between a printing position and a stop position, and wherein at least a first printing plate and at least a second printing plate are arranged at opposite sides of the at least one dispensing orifice, and wherein, in the printing position, the printing plates are arranged closer to the upper surface of a target substrate than in the stop position.

2. The printhead according to claim 1, further comprising at least one controller, wherein the at least one controller is configured and adapted to determine movement direction of the printhead, and wherein movement of the printing plates from the printing position to the stop position and from the stop position to the printing position is controlled by the at least one controller based on a detected printing position.

3. The printhead according to claim 1, wherein, in case where the at least the first printing plate is moved to or in the printing position, the at least the second printing plate is moved to or in the stop position reciprocally, and wherein movement between the printing position and the stop position of the printing plates is actuated pneumatically, hydraulically and/or by at least one electric motor that is triggered by the printing position, which is triggered by the at least one controller.

4. The printhead according to claim 1, further comprising:
a material feed mechanism for supplying extrusion material to the inlet port of the printhead such that the extrusion material is selectively forced through the at least one flow channel and exits through the at least one dispensing orifice.

5. The printhead according to claim 1, wherein the at least two printing plates are arranged in an adjustable angle α in a range of 30° to 70°relative to the upper surface of the target substrate, wherein the at least two printing plates have a thickness in a range of 0.05 to 0.5 mm, and wherein at least one of the at least two printing plates comprises or consists of stainless steel.

6. The printhead according to claim 1, further comprising:
at least one side wiper arranged at or adjacent to at least one of the at least two printing plates, wherein the at least one side wiper is configured and adapted to create a limited area for the movement and circulation of extrusion material, to provide an effective roll of the extrusion material at both printing directions, and to minimize hardening of extrusion material on the upper surface of the target substrate.

7. The printhead according to claim 1, further comprising:
a transport mechanism for supporting the printhead and/or the target substrate, and for moving the printhead relative to the target substrate such that extrusion material exiting the at least one dispensing orifice forms the at least one gridline on the upper surface of the target substrate.

8. The printhead according to claim 7 further comprising:
a controller for controlling a material feed mechanism and the transport mechanism such that:
during a first time period, the material feed mechanism forces an extrusion material through the at least one dispensing orifice while the transport mechanism moves the printhead over the target substrate in a first direction such that first structures are formed on the target substrate starting from or adjacent to a first side edge of the target substrate, wherein at least the first printing plate is in the printing position and at least the second printing plate is in the stop position, and
during a second time period, the material feed mechanism forces the extrusion material through the at least one dispensing orifice, while the transport mechanism moves the printhead over the target substrate in a second direction opposite to the first direction such that the first structure and/or second structures are formed on the target substrate, wherein the at least the second printing plate is in the printing position and at least the at least the first printing plate is in the stop position.

9. The printhead according to claim 1, further comprising a connection to integrated software of a printing machine that is configured to indicate a present printing mode, wherein the software is capable of triggering the at least two printing plates to start the movement according to the position and perform the function continuously.

10. Use of a printhead according to claim 1 for producing and/or within production of a solar cell.

11. A method for producing a plurality of parallel gridlines on an upper surface of a target substrate for producing a pattern solar cell structure by screen or stencil printing using a printhead, wherein the method comprises:
during a first time period, causing a material feed mechanism to force a gridline material through at least one dispensing orifice while causing a transport mechanism to move the printhead relative to the target substrate such that first structures are formed on the target substrate starting from or adjacent to a first side edge of the target substrate in a first direction, wherein a first printing blade is in the printing position and a second printing blade is in the stop position; and
during a second time period following the first time period, causing the material feed system to force said the gridline material through the at least one dispensing orifice while causing the transport mechanism to move the printhead relative to the target substrate in a second direction opposite to the first direction such that first and/or second structures are formed on the target substrate, wherein the second printing blade is in the printing position and the first printing blade is in the stop position.

12. A printhead for producing at least one gridline on an upper surface of a target substrate by screen or stencil printing, the printhead comprising:
at least one inlet port;
at least one dispensing orifice;
one or more flow channels communicating between the at least one inlet port and the at least one dispensing orifice; and
at least two printing blades that are placed in independently definable angles relative to the upper surface of the target substrate, wherein the at least two printing blades are independently movable between a printing position and a stop position, and wherein at least a first printing blade and at least a second printing blade are arranged at opposite sides of the at least one dispensing orifice, and wherein, in the printing position, the printing blades are arranged closer to the upper surface of a target substrate than in the stop position.
